(19) United States
(12) Patent Application Publication
(10) Pub. No.: US 2024/0288845 A1
(43) Pub. Date: Aug. 29, 2024

(54) INFORMATION PROCESSING APPARATUS AND STORAGE MEDIUM

(71) Applicant: CANON KABUSHIKI KAISHA, Tokyo (JP)

(72) Inventor: TOMOHIRO MASE, Tochigi (JP)

(21) Appl. No.: 18/581,643

(22) Filed: Feb. 20, 2024

(30) Foreign Application Priority Data
Feb. 28, 2023 (JP) 2023-030132

(51) Int. Cl. G05B 19/402; G03F 7/00; G03F 9/00

(52) U.S. Cl. CPC G05B 19/402; G03F 7/706839; G03F 9/7046; G05B 2219/41091

(57) ABSTRACT

An information processing apparatus includes a processor configured to determine, using a first regression model formed by a plurality of terms, a plurality of sample shot regions from a plurality of shot regions on a substrate, and a display controller configured to perform display control so that information of the plurality of sample shot regions determined by the processor is displayed on a user interface screen. The processor is configured to redetermine a plurality of sample shot regions using a second regression model formed by some terms of the plurality of terms, and the display controller is configured to update display of the user interface screen so that information of the plurality of sample shot regions redetermined by the processor is displayed on the user interface screen.

### BACKGROUND OF THE INVENTION

### Field of the Invention

The present disclosure relates to an information processing apparatus and a storage medium.

### Description of the Related Art

An exposure apparatus can overlay the pattern of an original on a plurality of layers on a substrate and transfer it. To overlay the layers accurately, it is necessary to align each shot region of the substrate with the original. For example, an alignment mark arranged in each shot region on the substrate can be detected, and then the alignment can be performed based on position information of the alignment mark obtained by the detection and position information of the pattern of the original.

To implement accurate alignment, it is ideal to detect the alignment marks in all the shot regions on the substrate. However, this is not realistic from the viewpoint of productivity. Therefore, in general, a global alignment method is adopted to align all shot regions on a substrate and an original (see Japanese Patent Laid-Open Nos. 61-44429 and 62-84516).

In the global alignment method, it is assumed that the relative position of each of all shot regions on a substrate can be expressed by a function of the position coordinates of the shot region. Under this assumption, alignment marks only in some shot regions (sample shot regions) among the plurality of shot regions on the substrate are actually measured. Next, the parameters of the function model are estimated, using regression analysis-like statistic operation processing, from the assumed function model and the position measurement result. Using the estimated parameters and the function model, the position coordinates of each shot region on a stage coordinate system are calculated, thereby performing alignment. In the global alignment method, a polynomial model using stage coordinates as variables is used in general. Scaling that is a first-order polynomial of stage coordinates, rotation, uniform offset, and the like are mainly used (see Japanese Patent Laid-Open No. 6-349705).

There is also proposed a method using a regression model that considers, as a parameter, even a high-order component of the array of shot regions on the substrate (see Japanese Patent No. 3230271). Furthermore, there is proposed a method of measuring a plurality of sample points in advance, selecting a coefficient by a regression model having a regularization term and the data, and calculating position information of a shot region using the selected coefficient.

To perform accurate correction with a small number of sample shot regions (sample points), a method of accurately predicting (without overfitting) a high-order component of a substrate using a model of a high degree of freedom has been studied. This method can include, for example, creating, from a first regression model formed by a plurality of terms, a second regression model formed by some terms of the plurality of terms, and determining a plurality of sample shot regions using the second regression model.

However, to confirm the effect, it is currently necessary to calculate an overlay error by performing actual measurement using a parameter determined by prediction with respect to the created second regression model. Therefore, it is desired to readily predict, without performing such actual measurement, influence exerted when comparing parameters before and after prediction or adjusting a parameter.

### SUMMARY OF THE INVENTION

The present disclosure provides a technique advantageous in readily confirming the effect of adjustment of a parameter associated with processing of determining sample shot regions.

The present invention in its aspect provides an information processing apparatus including a processor configured to determine, using a first regression model formed by a plurality of terms, a plurality of sample shot regions from a plurality of shot regions on a substrate, and a display controller configured to perform display control so that information of the plurality of sample shot regions determined by the processor is displayed on a user interface screen, wherein the processor is configured to redetermine a plurality of sample shot regions using a second regression model formed by some terms of the plurality of terms, and the display controller is configured to update display of the user interface screen so that information of the plurality of sample shot regions redetermined by the processor is displayed on the user interface screen.

Further features of the present invention will become apparent from the following description of exemplary embodiments (with reference to the attached drawings).

### BRIEF DESCRIPTION OF THE DRAWINGS

FIG. 1 is a view showing the arrangement of an exposure apparatus;

FIG. 2 is a view showing the arrangement of an alignment optical system;

FIG. 3 is a flowchart of exposure processing;

FIG. 4 is a view showing an example of sample shot regions;

FIG. 5 is a graph exemplifying the relationship between the number of sample points and a correction residual;

FIG. 6 is a view showing an example of a user interface screen;

FIG. 7 is a view showing an example of the user interface screen;

FIG. 8 is a view showing an example of the user interface screen;

FIG. 9 is a view showing an example of the user interface screen;

FIG. 10 is a view showing an example of the user interface screen; and

FIG. 11 is a view showing an example of the user interface screen.

FIG. 12 is a view showing a polynomial display screen.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

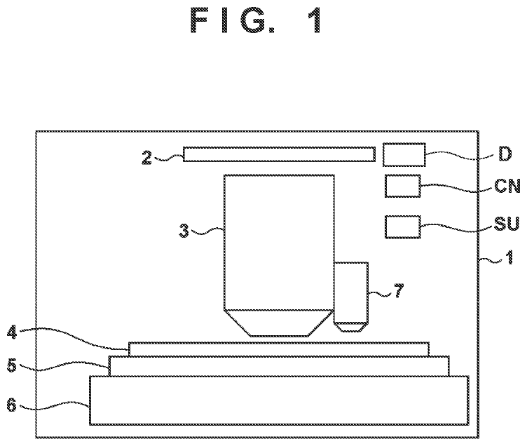

FIG. 1 is a view showing the arrangement of an exposure apparatus 1 according to the embodiment. The exposure apparatus 1 is a lithography apparatus used in the manufacturing step of a device such as a semiconductor element. In this embodiment, the exposure apparatus 1 projects the pattern of an original 2 (a reticle or a mask) onto a substrate 4 via a projection optical system 3, and exposes the substrate 4.

As shown in FIG. 1, the exposure apparatus 1 includes the projection optical system 3 that projects (reduction-projects) a pattern formed on the original 2, and a chuck 5 that holds the substrate 4 on which a base pattern or an alignment mark is formed by a preprocess. The exposure apparatus 1 also includes a substrate stage 6 that holds the chuck 5 and positions the substrate 4 at a predetermined position, an alignment optical system 7 that measures the position of an alignment mark provided on the substrate 4, a controller CN, a storage unit SU, and a display unit D.

The controller CN is formed by, for example, a computer (information processing apparatus) including a CPU and a memory, and generally controls the units of the exposure apparatus 1 in accordance with a program stored in the storage unit SU or the like. In this embodiment, in addition to controlling exposure processing of exposing the substrate 4 via the original 2, the controller CN can function as a processor configured to obtain an array (a shot array or a region array) of a plurality of shot regions on the substrate (a plurality of regions on the substrate). On the display unit D, a user interface screen (UI screen) showing the setting, state, and the like of exposure processing is displayed. The controller CN can function as a display controller configured to control display of the UI screen.

The storage unit SU stores a program and various kinds of information (data) necessary to execute exposure processing of exposing the substrate 4 by controlling the units of the exposure apparatus 1. The storage unit SU also stores a program and various kinds of information (data) necessary for the controller CN to obtain the arrangement of the sample shot regions. Note that the controller CN, the storage unit SU, and the display unit D may be formed as external devices of the exposure apparatus 1. For example, an information processing apparatus including the controller CN, the storage unit SU, and the display unit D may be formed as a server apparatus configured to manage the exposure apparatus 1. Alternatively, an information processing apparatus including the controller CN, the storage unit SU, and the display unit D may be formed as a simulation apparatus configured to perform simulation for determining sample shot regions. An input device (a mouse, a keyboard, or the like) (not shown) operated by the user is also connected to the controller CN. Note that the storage unit SU may be a semiconductor memory, a disk such as a hard disk, or a memory in another form. A program for obtaining the arrangement of the sample shot regions may be stored in a computer-readable memory medium or may be provided to an information processing apparatus via a communication facility such as an electric communication network.

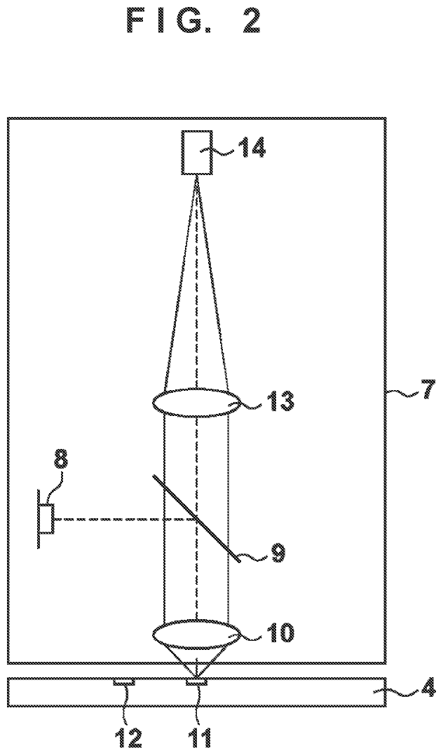

FIG. 2 is a schematic view showing the arrangement of the alignment optical system 7. The alignment optical system 7 has a function of optically detecting a mark assigned to each shot region on the substrate 4 and acquiring position measurement data, and, in this embodiment, includes a light source 8, a beam splitter 9, lenses 10 and 13, and a sensor 14.

Light from the light source 8 is reflected by the beam splitter 9 and illuminates, via the lens 10, an alignment mark 11 or 12 provided on the substrate 4. The light diffracted by the alignment mark 11 or 12 is received by the sensor 14 via the lens 10, the beam splitter 9, and the lens 13.

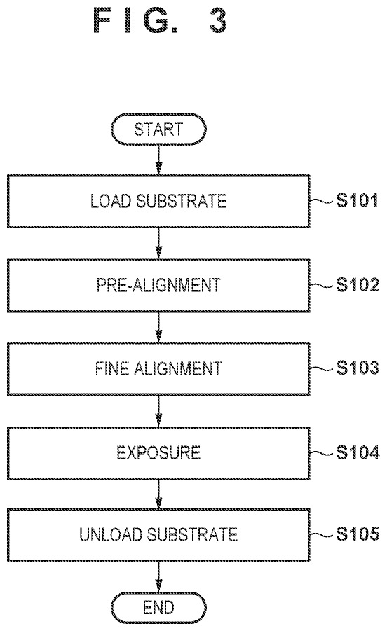

Exposure processing by the exposure apparatus 1 will be described with reference to FIG. 3. The outline of steps until the substrate 4 is aligned and exposed will be described here. In step S101, the substrate 4 is loaded into the exposure apparatus 1. In step S102, the controller CN executes pre-alignment. More specifically, the controller CN detects the alignment mark 11 for pre-alignment provided on the substrate 4 using the alignment optical system 7, thereby roughly obtaining the position of the substrate 4. At this time, detection of the alignment mark 11 is performed for a plurality of shot regions on the substrate 4, and the shift and the first-order linear component (magnification or rotation) of the entire substrate 4 are obtained.

In step S103, the controller CN executes fine alignment. More specifically, first, based on the result of pre-alignment, the controller CN drives the substrate stage 6 to a position where the alignment mark 12 for fine alignment provided on the substrate 4 can be detected by the alignment optical system 7. Then, the controller CN detects, using the alignment optical system 7, the alignment mark 12 provided in each of the plurality of shot regions on the substrate 4, thereby precisely obtaining the shift and the first-order linear component (magnification or rotation) of the entire substrate 4. At this time, the controller CN can also precisely obtain the high-order deformation component of the substrate 4 by obtaining the positions of a number of shot regions. This makes it possible to obtain the precise position of each shot region on the substrate 4, that is, the shot array.

In step S104, the controller CN exposes the substrate 4. More specifically, after the fine alignment is executed, the controller CN transfers the pattern of the original 2 to each shot region on the substrate 4 via the projection optical system 3. In step S105, the substrate 4 is unloaded from the exposure apparatus 1.

In this embodiment, if the substrate 4 is distorted, the high-order deformation component is corrected in the fine alignment of step S103. As a regression model used to estimate the shot array, a fifth-order polynomial model is used. However, the regression model is not limited to this. For example, as the regression model, an arbitrary order model can be used. A model (a triangle function model or a logarithmic model) other than a polynomial model may be used.

If the deformation of the substrate is expressed by a fifth-order polynomial model, the position deviations (ShiftX, ShiftY) of each shot region are represented by equations (1) below. Note that a position deviation of each shot region may be understood as a correction value used to correct the position deviation.

$$ShiftX = {k}_{1} + {k}_{3} x + {k}_{5} y + {k}_{7} {x}^{2} + {k}_{9} xy + {k}_{11} {y}^{2} + {k}_{13} {x}^{3} + {k}_{15} {x}^{2} y + {k}_{17} {xy}^{2} + {k}_{19} {y}^{3} + {k}_{21} {x}^{4} + {k}_{23} {x}^{3} y + {k}_{25} {x}^{2} {y}^{2} + {k}_{27} {xy}^{3} + {k}_{29} {y}^{4} + {k}_{31} {x}^{5} + {k}_{33} {x}^{4} y + {k}_{35} {x}^{3} {y}^{2} + {k}_{37} {x}^{2} {y}^{3} + {k}_{39} {xy}^{4} + {k}_{41} {y}^{5} \qquad ( 1 )$$

$$ShiftY = {k}_{2} + {k}_{4} y + {k}_{6} x + {k}_{8} {y}^{2} + {k}_{10} xy + {k}_{12} {x}^{2} + {k}_{14} {y}^{3} + {k}_{16} {xy}^{2} + {k}_{18} {x}^{2} y + {k}_{20} {x}^{3} + {k}_{22} {y}^{4} + {k}_{24} {xy}^{3} + {k}_{26} {x}^{2} {y}^{2} + {k}_{28} {x}^{3} y + {k}_{20} {x}^{4} + {k}_{32} {y}^{5} + {k}_{34} {xy}^{4} + {k}_{36} {x}^{2} {y}^{3} + {k}_{38} {x}^{3} {y}^{2} + {k}_{40} {x}^{4} y + {k}_{42} {x}^{5}$$

where x and y represent the positions of a shot region on the substrate 4. Coefficients k₁ to k₄₂ in equations (1) are determined based on the actual position measurement data of each shot region on the substrate 4. Then, the position deviation (correction value) of each shot region is obtained based on equations (1) in which the coefficients are determined.

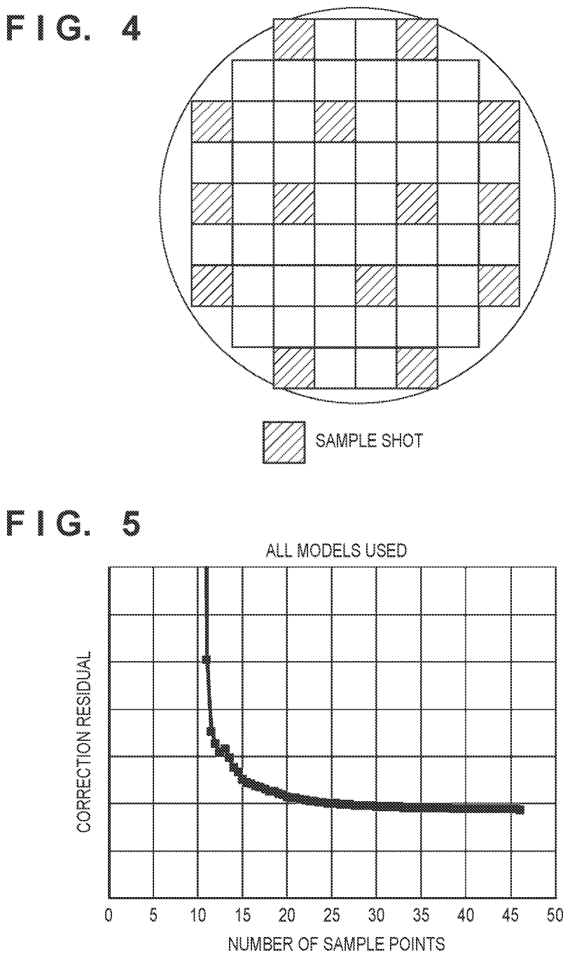

In the global alignment method, alignment measurement is executed in sample shot regions which are some of the plurality of shot regions on the substrate. FIG. 4 shows an example of the sample shot regions. Referring to FIG. 4, as an example, 14 sample shot regions are set on the substrate. In the global alignment method, the alignment mark 12 arranged in each of these sample shot regions is detected using the alignment optical system 7.

FIG. 5 is a graph showing an example of the relationship between the number of sample shot regions (the number of sample points) and a correction residual as an index of correction accuracy in a given device. The correction residual indicates an array error that cannot completely be corrected when correcting the array of the plurality of shot regions on the substrate using the plurality of determined sample shot regions. From the viewpoint of correction accuracy (measurement accuracy), the number of sample shot regions as actual measurement targets is desirably large. However, as the number of sample shot regions is larger, it is more disadvantageous in terms of measurement throughput. The number of sample shot regions is appropriately determined based on the tradeoff relationship between the correction accuracy and the throughput.

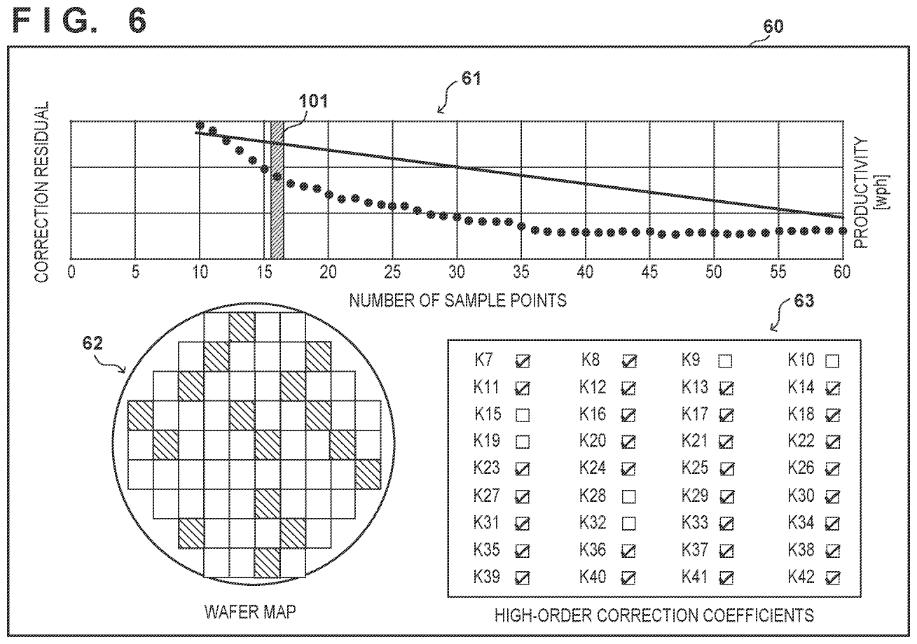

FIG. 6 is a view showing an example of a user interface (UI) screen 60 displayed on the display unit D concerning decision of sample shot regions. The UI screen 60 can include a graph display screen 61 showing the relationship between the number of sample points and each of the correction residual and productivity, a wafer map display screen 62 showing the result of the arrangement of the sample shot regions on the substrate, and a coefficient display screen 63 showing the application status of the coefficient of each term forming the regression model.

In the example shown in FIG. 6, on the graph display screen 61, a graph showing transition of the correction residual with respect to the number of sample points and a graph showing transition of productivity with respect to the number of sample points are displayed. In this example, the productivity is expressed by the number of substrates processed per unit time (wph). With reference to the graphs displayed on the graph display screen 61, the user can search for the number of sample points with which it is possible to make a compromise with respect to the correction residual and the productivity. In an example, the controller CN serving as a processor determines a recommended value (the initial number of sample points) of the number of sample points based on the relationship between the number of sample points and each of the correction residual and productivity. After that, the controller CN provisionally decides the arrangement of the sample shot regions by the initial number of sample points in accordance with a predetermined selection algorism. As the selection algorism, a known algorism can be used. The selection algorism is, for example, an algorism of making a selection under a predetermined constraint such as the constraint that the set number of sample shot regions are equally arranged (without localization) symmetrically with respect to the center of the substrate as much as possible or the constraint that the set number of sample shot regions are arranged outside the substrate as many as possible. A further constraint that the shot region on the outermost periphery of the substrate is excluded from selection targets may be placed.

After that, the controller CN determines the arrangement of the sample shot regions by a method using a regression model with respect to the provisionally determined arrangement of the sample shot regions. The decision method can include, for example, a first step of creating, from a first regression model formed by a plurality of terms, a second regression model formed by some terms of the plurality of terms, and a second step of determining the arrangement of the sample shot regions using the second regression model. The controller CN controls the UI screen 60 so that information of the determined arrangement of the sample shot regions is displayed on the wafer map display screen 62.

Furthermore, the controller CN controls the UI screen 60 so that the application status of the coefficient of each term forming the second regression model is displayed on the coefficient display screen 63. In this example, since the fifth-order polynomial model is assumed as the first regression model, the high-order correction coefficients k₁ to k₄₂ are displayed, on the coefficient display screen 63, as candidates to be applied. Then, among them, coefficients applied to the finally used regression model are identifiably displayed on the coefficient display screen 63. For example, in the example shown in FIG. 6, the presence/absence of application is displayed by ON/OFF of a checkbox corresponding to each coefficient. The coefficient whose checkbox is ON is applied to the regression model, and the coefficient whose checkbox is OFF is not applied to the regression model.

The number of sample points can be changed by a user operation. For example, when a mouse pointer overlaps the graph of the graph display screen 61, a partial region 101 including the position of the mouse pointer is displayed in a specific color by the rollover effect. If the mouse is clicked in this state, the number of sample points corresponding to the partial region 101 is set. In this way, the user can designate the number of sample shot regions. That is, in this embodiment, the graph display screen 61 is a designation screen used by the user to designate the number of sample shot regions.

The wafer map display screen 62 is a display screen that displays information of the position of each of the plurality of sample shot regions on the substrate. When the number of sample points is designated or changed, the controller CN redetermines the arrangement of the shot regions. After that, the controller CN updates the display so that the redetermined arrangement of the sample shot regions is displayed on the wafer map display screen 62. Furthermore, the controller CN updates the display so that the coefficients applied to the regression model when redetermining the arrangement of the sample shot regions are displayed on the coefficient display screen 63.

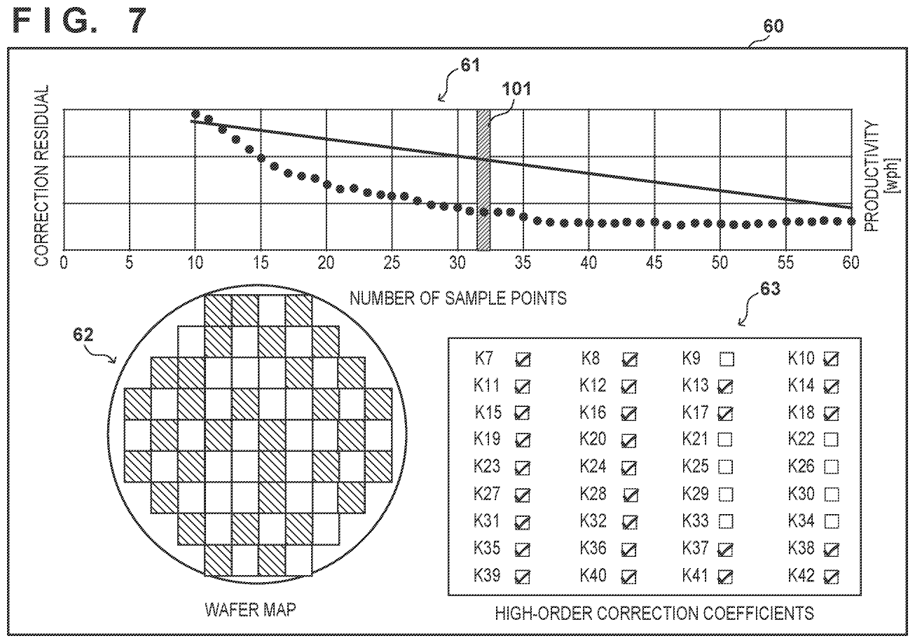

FIG. 6 shows a result in a case where 16 sample points are set. FIG. 7 shows a result in a case where 32 sample points are set. In this way, with respect to the number of sample points arbitrarily designated by the user, the predicted correction accuracy and productivity, an optimum arrangement of the sample shot regions, and the presence/absence of application of each high-order correction coefficient are displayed. This allows the user to readily confirm the effect of adjustment of the parameter for determining the sample shot regions.

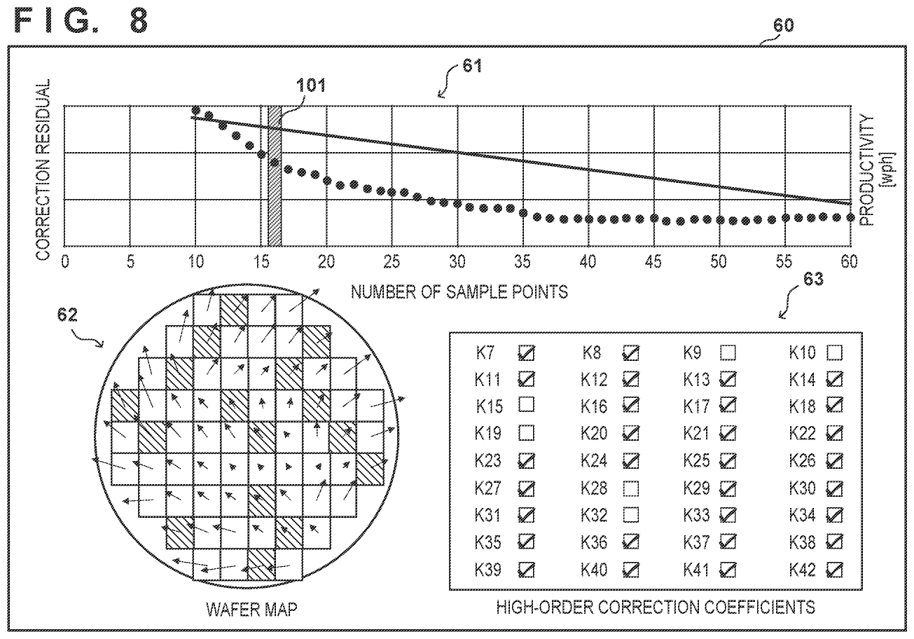

The correction residual for each shot region may be displayed on the wafer map display screen 62. For example, as shown in FIG. 8, on the wafer map display screen 62, the correction residual of each shot region may be displayed by an arrow representing the direction and magnitude on the X-Y plane. This allows the user to readily confirm the correction effect for each shot region. The display by the arrow representing the direction and magnitude on the X-Y plane will also be referred to as “vector display” hereinafter. The display of the direction and magnitude of the correction residual of each shot region is not limited to the display form shown in FIG. 8. For example, the magnitude in each of the X and Y directions of the correction residual of each shot region may be displayed by an arrow or a numerical value.

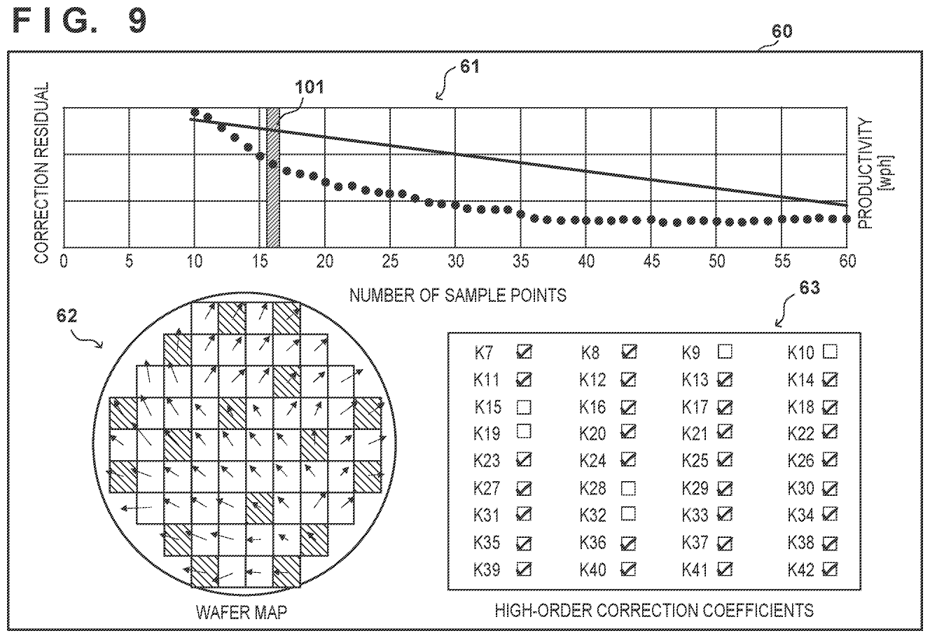

In an example, the user can change the arrangement of the sample shot regions on the wafer map display screen 62 by operating the mouse and/or keyboard. For example, the user can move an arbitrary sample shot region to another region by dragging it using the mouse. If the arrangement of the sample shot regions is changed, the controller CN recalculates the correction residual, and updates the vector display of the correction residual of each shot region. FIG. 9 shows an example in which the arrangement of the sample shot regions shown in FIG. 8 is changed by a user operation. In this example, some sample shot regions are moved to the peripheral side of the substrate to decrease the correction residual on the peripheral side of the substrate. In this case, however, the sample shot regions arranged near the center of the substrate are coarse, the correction residual near the center of the substrate may be sacrificed. The user can compare the correction residuals before and after the sample shot regions are moved, as shown in FIGS. 8 and 9. This makes it easy to confirm/compare the correction effect (between a plurality of conditions with the same productivity) obtained by changing the arrangement of the sample shot regions.

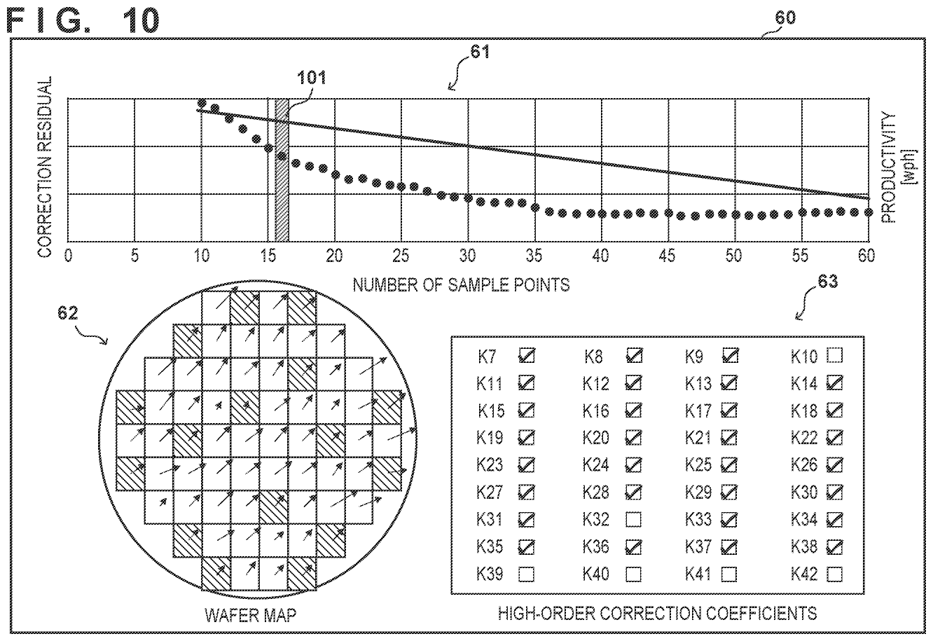

In an example, the user can change ON/OFF of each checkbox on the coefficient display screen 63 by operating the mouse and/or keyboard. That is, the coefficient display screen 63 is a selection screen for selecting some or all of the plurality of terms forming the regression model by user designation. This changes the application status of the coefficient of each term forming the second regression model. If ON/OFF of any of the checkboxes on the coefficient display screen 63 is changed, the controller CN recalculates the correction residual, and updates the vector display of the correction residual of each shot region. Referring to FIG. 10, the combination of the high-order correction coefficients for the arrangement of the sample shot regions shown in FIG. 9 is changed. For example, if it is considered, from the tendency of the correction residual, that a specific high-order correction coefficient tends to be excessively corrected, the user can turn off the checkbox of the coefficient. After that, if the correction residual is recalculated and the vector display of the correction residual of each shot region is updated, the user can view the tendency of the change of the correction residual. In this way, it is possible to readily confirm/compare the correction effect (between a plurality of conditions with the same productivity) obtained by adjusting the application state of the high-order correction coefficient.

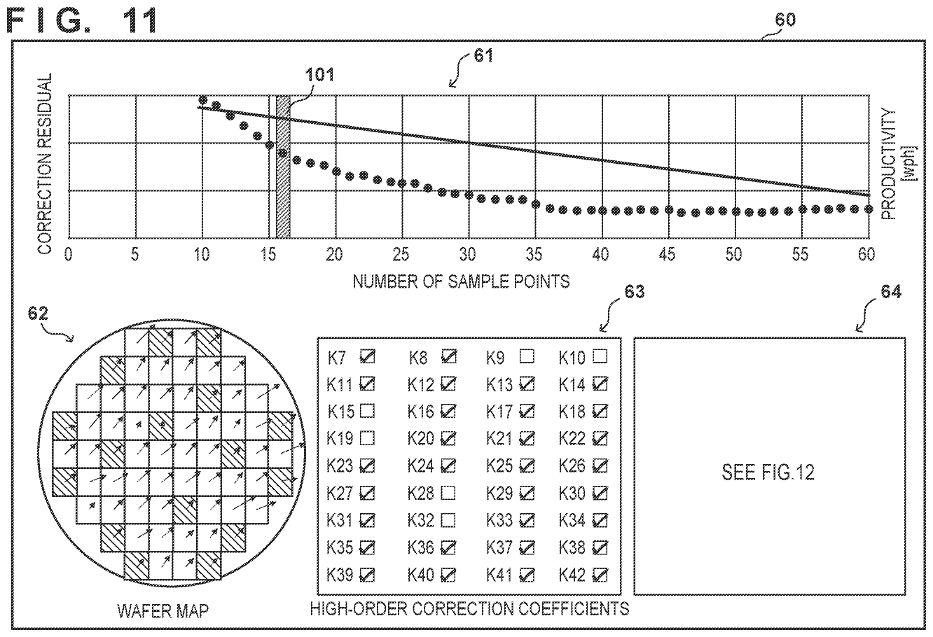

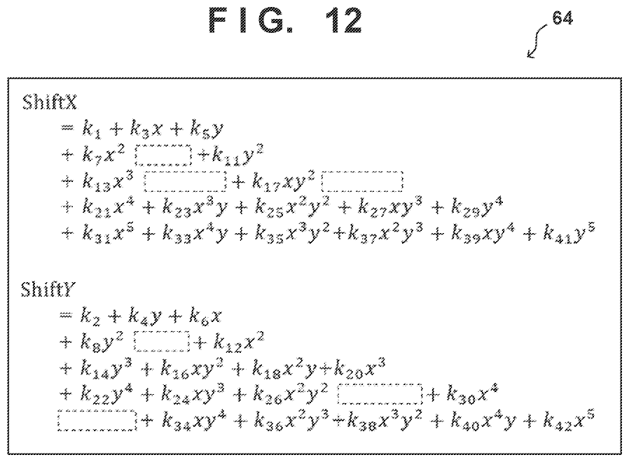

FIG. 11 shows an example in which the UI screen 60 additionally includes a polynomial display screen 64 of the regression model. A detailed example of the polynomial display screen 64 is shown in FIG. 12. On the polynomial display screen 64, terms used in the fifth-order polynomial and terms not used in the fifth-order polynomial are identifiably displayed in the application states of the high-order correction coefficients. Thus, it is possible to readily grasp the correction accuracy and productivity predicted with respect to the application states of the high-order correction coefficients and calculation formulas corresponding to them.

### <Embodiment of Method of Manufacturing Article>

A method of manufacturing an article according to the embodiment of the present disclosure is suitable for manufacturing an article, for example, a microdevice such as a semiconductor device or an element having a fine structure. The method of manufacturing an article according to the embodiment includes a step of forming, using the above-described exposure apparatus, a latent image pattern on a photosensitive agent applied on a substrate (a step of exposing the substrate), and a step of developing the substrate on which the latent image pattern has been formed in the above step. In addition, the manufacturing method includes other well-known steps (oxidation, film formation, deposition, doping, planarization, etching, resist removal, dicing, bonding, packaging, and the like). The method of manufacturing an article according to this embodiment is more advantageous than the conventional methods in at least one of the performance, quality, productivity, and production cost of the article.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-030132, filed Feb. 28, 2023, which is hereby incorporated by reference herein in its entirety.

What is claimed is:

1. An information processing apparatus comprising:
a processor configured to determine, using a first regression model formed by a plurality of terms, a plurality of sample shot regions from a plurality of shot regions on a substrate; and
a display controller configured to perform display control so that information of the plurality of sample shot regions determined by the processor is displayed on a user interface screen,
wherein the processor is configured to redetermine a plurality of sample shot regions using a second regression model formed by some terms of the plurality of terms, and
the display controller is configured to update display of the user interface screen so that information of the plurality of sample shot regions redetermined by the processor is displayed on the user interface screen.

2. The apparatus according to claim 1, wherein
the user interface screen includes a selection screen for selecting the some terms from the plurality of terms by user designation, and
the second regression model is formed by the some terms selected via the selection screen.

3. The apparatus according to claim 2, wherein the selection screen includes a checkbox for designating selection of each of the plurality of terms.

4. The apparatus according to claim 2, wherein the processor is configured to redetermine, in response to a change of the some terms via the selection screen, a plurality of sample shot regions using the second regression model formed by the changed some terms.

5. The apparatus according to claim 1, wherein the processor is configured to redetermine, in response to designation of the number of sample shot regions by a user, a plurality of sample shot regions using the second regression model.

6. The apparatus according to claim 5, wherein the user interface screen includes a designation screen used by the user to designate the number of sample shot regions.

7. The apparatus according to claim 1, wherein
the information of the plurality of sample shot regions includes information of a position of each of the plurality of sample shot regions on the substrate, and
the user interface screen includes a display screen that displays the position of each of the plurality of sample shot regions on the substrate.

8. The apparatus according to claim 7, wherein
the information of the plurality of sample shot regions further includes information of a correction residual of each of the plurality of shot regions in a case where an array of the plurality of shot regions is corrected using the plurality of sample shot regions, and
the display controller is configured to display the information of the correction residual of each of the plurality of shot regions on the display screen.

9. The apparatus according to claim 8, wherein the display controller is configured to display, by vector display, the information of the correction residual of each of the plurality of shot regions.

10. The apparatus according to claim 2, wherein the user interface screen further includes a display screen that displays a polynomial representing the second regression model formed by the some terms selected via the selection screen.

11. An information processing apparatus comprising:
a processor configured to perform processing of determining a plurality of sample shot regions from a plurality of shot regions on a substrate; and
a display controller configured to control display of a user interface screen,
wherein the processor is configured to
acquire the number of sample shot regions designated by a user, and
determine the acquired number of sample shot regions using a second regression model formed by some terms of a plurality of terms forming a first regression model, and
the display controller is configured to display, on the user interface screen, information of the determined sample shot regions and information of a polynomial forming the second regression model.

12. An information processing apparatus for performing display control of a user interface screen, comprising:
an acquirer configured to acquire first information concerning a second regression model formed by some terms of a plurality of terms forming a first regression model for correcting an array of a plurality of shot regions on a substrate, second information concerning a correction residual in a case where the array of the plurality of shot regions is corrected using the second regression model, and third information concerning sample shot regions determined from the plurality of shot regions based on a relationship between the number of sample shot regions and the correction residual; and
a display controller configured to perform display control so that the first information, the second information, and the third information acquired by the acquirer are displayed on the user interface screen.

13. A computer-readable storage medium storing a program, the program including a program code for causing a computer to function as:
a processor configured to determine, using a first regression model formed by a plurality of terms, a plurality of sample shot regions from a plurality of shot regions on a substrate; and
a display controller configured to perform display control so that information of the plurality of sample shot regions determined by the processor is displayed on a user interface screen,
wherein the processor is configured to redetermine a plurality of sample shot regions using a second regression model formed by some terms of the plurality of terms, and
the display controller is configured to update display of the user interface screen so that information of the plurality of sample shot regions redetermined by the processor is displayed on the user interface screen.

14. A computer-readable storage medium storing a program, the program including a program code for causing a computer to function as:
a processor configured to perform processing of determining a plurality of sample shot regions from a plurality of shot regions on a substrate; and
a display controller configured to control display of a user interface screen,
wherein the processor is configured to
acquire the number of sample shot regions designated by a user, and
determine the acquired number of sample shot regions using a second regression model formed by some terms of a plurality of terms forming a first regression model, and
the display controller is configured to display, on the user interface screen, information of the determined sample shot regions and information of a polynomial forming the second regression model.

15. A computer-readable storage medium storing a program, the program including a program code for causing a computer to function as:
an acquirer configured to acquire first information concerning a second regression model formed by some terms of a plurality of terms forming a first regression model for correcting an array of a plurality of shot regions on a substrate, second information concerning a correction residual in a case where the array of the plurality of shot regions is corrected using the second regression model, and third information concerning sample shot regions determined from the plurality of shot regions based on a relationship between the number of sample shot regions and the correction residual; and
a display controller configured to perform display control so that the first information, the second information, and the third information acquired by the acquirer are displayed on a user interface screen.
